(19) United States
(12) Patent Application Publication
(10) Pub. No.: US 2020/0287509 A1
(43) Pub. Date: Sep. 10, 2020

(54) OPERATIONAL AMPLIFIER

(71) Applicants: Kabushiki Kaisha Toshiba, Tokyo (JP); Toshiba Electronic Devices & Storage Corporation, Tokyo (JP)

(72) Inventors: Shuji Toda, Kawasaki Kanagawa (JP); Atsushi Namai, Kawasaki Kanagawa (JP)

(21) Appl. No.: 16/559,321

(22) Filed: Sep. 3, 2019

(30) Foreign Application Priority Data
Mar. 5, 2019 (JP) 2019-039523

(51) Int. Cl. H03F 3/45; H03F 1/02

(52) U.S. Cl. CPC H03F 3/45219; H03F 1/0211; H03F 2203/45298; H03F 2203/45352; H03F 2203/45344

(57) ABSTRACT

According to one embodiment, an operational amplifier includes first and second input terminals, an output terminal, differential circuitry, and output circuitry. The differential circuitry including first and second nodes, and first and second transistors. The output circuitry including third through fifth nodes, and third through eighth transistors. The third transistor being coupled to the first node at a gate and coupled to the third node at one end. The fourth transistor being coupled to the second node at a gate and coupled to the fourth node at one end. The fifth transistor being coupled to the fourth node at a gate and coupled to the third node at one end. The sixth transistor being coupled to the fourth node at each of a gate and one end.

### CROSS-REFERENCE TO RELATED APPLICATIONS

This application is based upon and claims the benefit of priority from Japanese Patent Application No. 2019-039523, filed Mar. 5, 2019, the entire contents of which are incorporated herein by reference.

### FIELD

Embodiments described herein relate to an operational amplifier.

### BACKGROUND

Operational amplifiers capable of rail-to-rail input and output operation are known.

### BRIEF DESCRIPTION OF THE DRAWINGS

FIG. 1 is a block diagram illustrating a configuration example of an operational amplifier according to a first embodiment.

FIG. 2 is a circuit diagram of differential circuitry included in the operational amplifier according to the first embodiment.

FIG. 3 is a circuit diagram of output circuitry included in the operational amplifier according to the first embodiment.

FIG. 4 is a block diagram illustrating a configuration example of an operational amplifier according to a comparative example of the first embodiment.

FIG. 5 is a circuit diagram of output circuitry included in the operational amplifier according to the comparative example of the first embodiment.

FIG. 6 is a graph illustrating an example of a relationship between an input voltage and an offset voltage, in each of the operational amplifier according to the first embodiment and the operational amplifier according to the comparative example of the first embodiment.

FIG. 7 is a circuit diagram of output circuitry included in an operational amplifier according to a second embodiment.

### DETAILED DESCRIPTION

In general, according to one embodiment, an operational amplifier includes a first input terminal, a second input terminal, an output terminal, differential circuitry, and output circuitry. The differential circuitry including a first node, a second node, a first transistor, and a second transistor. The first transistor being coupled to the first input terminal at a gate and coupled to the first node at one end. The second transistor being coupled to the second input terminal at a gate, coupled to the second node at one end, and coupled to another end of the first transistor at another end. The output circuitry including a third node, a fourth node, a fifth node, a third transistor, a fourth transistor, a fifth transistor, a sixth transistor, a seventh transistor, and an eighth transistor. The fifth node being coupled to the output terminal. The third transistor being coupled to the first node at a gate and coupled to the third node at one end. The fourth transistor being coupled to the second node at a gate and coupled to the fourth node at one end. The fifth transistor being coupled to the fourth node at a gate and coupled to the third node at one end. The sixth transistor being coupled to the fourth node at each of a gate and one end. The seventh transistor being coupled to the second node at a gate and coupled to the fifth node at one end. The eighth transistor being coupled to the third node at a gate and coupled to the fifth node at one end.

Hereinafter, embodiments will be described with reference to the accompanying drawings. Each of the embodiments is an example of an apparatus and a method to embody a technical idea of the invention. The drawings are schematic or conceptual, and the dimensions and ratios, etc. in the drawings are not always the same as the actual ones. The technical ideas of the present invention are not limited by shapes, structures, or arrangements, etc. of the components.

In the description that follows, components having substantially the same functions and configurations will be denoted by the same reference symbols. The numbers after the letters constituting the reference symbols are used to discriminate between components that are denoted by the reference symbols sharing letters in common and that have similar configurations. If there is no need to discriminate between components that are denoted by the reference symbols sharing letters in common, such components are denoted by reference symbols that include the letters only.

### [1] First Embodiment

Hereinafter, a description will be given of an operational amplifier 1 according to a first embodiment.

[1-1] Configuration of Operational Amplifier 1

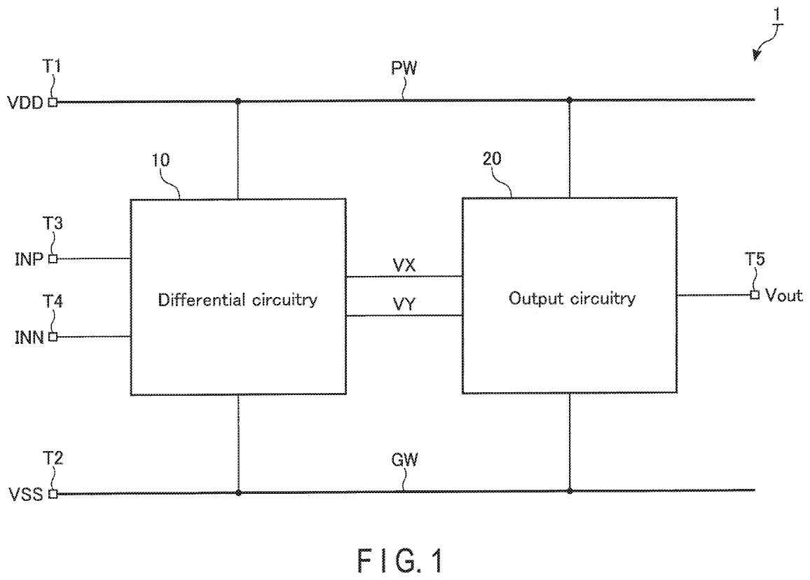

FIG. 1 is a configuration example of the operational amplifier 1 according to the first embodiment. The operational amplifier 1 is an operational amplifier capable of rail-to-rail input and output operation. As shown in FIG. 1, the operational amplifier 1 includes, for example, terminals T1-T5, differential circuitry 10, and output circuitry 20. In the operational amplifier 1, each of the terminals T1-T5 can be coupled to an external device, and the differential circuitry 10 and the output circuitry 20 are integrated on, for example, a single semiconductor chip.

The terminal T1 is a positive-side power-supply terminal of the operational amplifier 1, and is coupled to a power line PW. The terminal T1 is applied with, for example, a power-supply voltage VDD. The terminal T2 is a negative-side power-supply terminal of the operational amplifier 1, and is coupled to a power line GW. The terminal T2 is applied with, for example, a power-supply voltage VSS, which is lower than the power-supply voltage VDD. The terminal T3 is a non-inverting input terminal of the operational amplifier 1. A signal INP is input to the terminal T3. The terminal T4 is an inverting input terminal of the operational amplifier 1. A signal INN is input to the terminal T4. The terminal T5 is an output terminal of the operational amplifier 1. A signal Vout is output from the terminal T5.

The differential circuitry 10 is coupled to both of the power lines PW and GW and both of the terminals T3 and T4, and differentially amplifies the signal input to the terminal T3 and the signal input to the terminal T4. The differential circuitry 10 includes a pair of nodes VX and VY, to which the signals differentially amplified by the differential circuitry 10 are output.

The output circuitry 20 is coupled to both of the power lines PW and GW, the terminal T5, and both of the nodes VX and VY of the differential circuitry 10. The output circuitry 20 outputs, as a signal Vout, a voltage based on the voltage of each of the nodes VX and VY to the terminal T5.

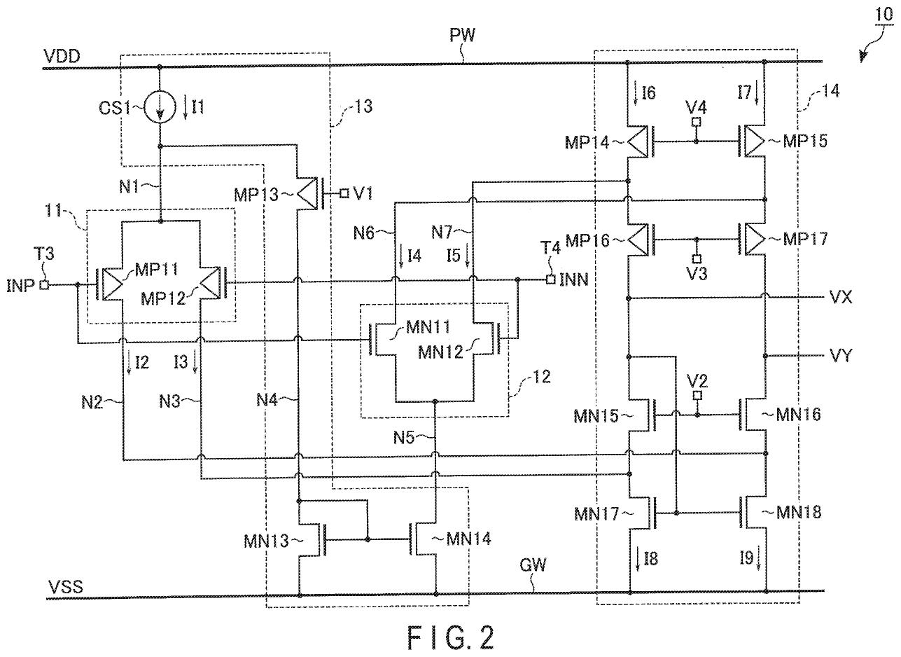

FIG. 2 illustrates an example of a circuit configuration of the differential circuitry 10 included in the operational amplifier 1 according to the first embodiment. As shown in FIG. 2, the differential circuitry 10 includes a first differential circuit 11, a second differential circuit 12, a current control circuit 13, and a folded cascode circuit 14.

The first differential circuit 11 differentially amplifies the signal input to the terminal T3 and the signal input to the terminal T4, and outputs the differentially amplified signals to the folded cascode circuit 14. The first differential circuit 11 includes, for example, transistors MP11 and MP12. Each of the transistors MP11 and MP12 is, for example, a p-type MOSFET.

The source of the transistor MP11 is coupled to a node N1. The gate of the transistor MP11 is coupled to the terminal T3. The drain of the transistor MP11 is coupled to a node N2. The source of the transistor MP12 is coupled to the node N1. The gate of the transistor MP12 is coupled to the terminal T4. The drain of the transistor MP12 is coupled to a node N3. In the present specification, the current that flows from the transistor MP11 into the node N2 will be referred to as a “current I2”, and the current that flows from the transistor MP12 into the node N3 will be referred to as a “current I3”.

The second differential circuit 12 differentially amplifies the signal input to the terminal T3 and the signal input to the terminal T4, and outputs the differentially amplified signals to the folded cascode circuit 14. The second differential circuit 12 includes, for example, transistors MN11 and MN12. Each of the transistors MN11 and MN12 is, for example, an n-type MOSFET.

The source of the transistor MN11 is coupled to a node N5. The gate of the transistor MN11 is coupled to the terminal T3. The drain of the transistor MN11 is coupled to a node N6. The source of the transistor MN12 is coupled to the node N5. The gate of the transistor MN12 is coupled to the terminal T4. The drain of the transistor MN12 is coupled to a node N7. In the present specification, the current that flows from the node N6 into the transistor MN11 will be referred to as a “current I4”, and the current that flows from the node N7 into the transistor MN12 will be referred to as a “current I5”.

The current control circuit 13 controls the currents that flow through the first differential circuit 11 and the second differential circuit 12, in accordance with the signals INP and INN. The current control circuit 13 includes, for example, a transistor MP13, transistors MN13 and MN14, and a constant current source CS1. The transistor MP13 is, for example, a p-type MOSFET. Each of the transistors MN13 and MN14 is, for example, an n-type MOSFET.

The constant current source CS1 is coupled between the power line PW and the node N1. The constant current source CS1 is applied with, for example, the power-supply voltage VDD, and supplies a current I1 to the node N1. The source of the transistor MP13 is coupled to the node N1. The drain of the transistor MP13 is coupled to a node N4. A voltage V1 is input to the gate of the transistor MP13. The drain and the gate of the transistor MN13 are coupled to the node N4. The source of the transistor MN13 is coupled to the power line GW. The drain of the transistor MN14 is coupled to the node N5. The source of the transistor MN14 is coupled to the power line GW. The gate of the transistor MN14 is coupled to the node N4.

The folded cascode circuit 14 amplifies the signals input from the first differential circuit 11 and the second differential circuit 12, and outputs the amplified signals to the nodes VX and VY. The folded cascode circuit 14 includes, for example, transistors MP14, MP15, MP16, and MP17, and transistors MN15, MN16, MN17, and MN18. Each of the transistors MP14, MP15, MP16, and MP17 is, for example, a p-type MOSFET. Each of the transistors MN15, MN16, MN17, and MN18 is, for example, an n-type MOSFET.

The source of the transistor MP14 is coupled to the power line PW. The drain of the transistor MP14 is coupled to the node N7. The gate of the transistor MP15 is coupled to the gate of the transistor MP14. The source of the transistor MP15 is coupled to the power line PW. The drain of the transistor MP15 is coupled to the node N6. The gates of the transistors MP14 and MP15 are applied with a voltage V4.

The source of the transistor MP16 is coupled to the node N7. The drain of the transistor MP16 is coupled to the node VX. The gate of the transistor MP17 is coupled to the gate of the transistor MP16. The source of the transistor MP17 is coupled to the node N6. The drain of the transistor MP17 is coupled to the node VY. The gates of the transistors MP16 and MP17 are respectively applied with a voltage V3.

The source of the transistor MN15 is coupled to the node N3. The drain of the transistor MN15 is coupled to the node VX. The gate of the transistor MN16 is coupled to the gate of the transistor MN15. The source of the transistor MN16 is coupled to the node N2. The drain of the transistor MN16 is coupled to the node VY. The gate of the transistor MN15 and the gate of the transistor MN16 are applied with the voltage V2. The source of the transistor MN17 is coupled to the power line GW. The gate of the transistor MN17 is coupled to the node VX. The drain of the transistor MN17 is coupled to the node N3. The source of the transistor MN18 is coupled to the power line GW. The gate of the transistor MN18 is coupled to the node VX. The drain of the transistor MN18 is coupled to the node N2.

Since the above-described differential circuitry 10 provides differential amplification, paired transistors are provided in, for example, a substantially equal size. That is, the paired transistors MP11 and MP12, MN11 and MN12, MP14 and the MP15, MP16 and MP17, MP15 and MP16, and MP17 and MP18 are respectively provided in a substantially equal size.

The sizes of the transistor MN13 and the transistor MN14 are, for example, substantially equal. The threshold voltages of the transistor MP11, the transistor MP12, and the transistor MP13 are, for example, substantially equal.

The above-described folded cascode circuit 14 includes two current paths. Specifically, the folded cascode circuit 14 includes, between the power lines PW and GW, a current path that runs through the transistors MP14, MP16, MN15, and MN17 in this order, and a current path that runs through the transistors MP15, MP17, MN16, and MN18 in this order. In the description that follows, the current that flows from the power line PW into the transistors MP14 and MP15 will be respectively denoted as “I6” and “I7”, and the current that flows from the transistors MN17 and MN18 into the power line GW will be respectively denoted as “I8” and “I9”.

Since the transistors MN17 and MN18 form a current mirror, the amounts of current flowing through the paired transistors in the folded cascode circuit 14, whose gates are commonly coupled, are substantially equal when an in-phase input voltage is input to the terminals T3 and T4, and a differential signal is not input thereto. Specifically, the amounts of current flowing through the transistors MP14 and MP15 are substantially equal; the amounts of current flowing through the transistors MP16 and MP17 are substantially equal; the amounts of current flowing through the transistors MN15 and MN16 are substantially equal; and the amounts of current flowing through the transistors MN17 and MN18 are substantially equal.

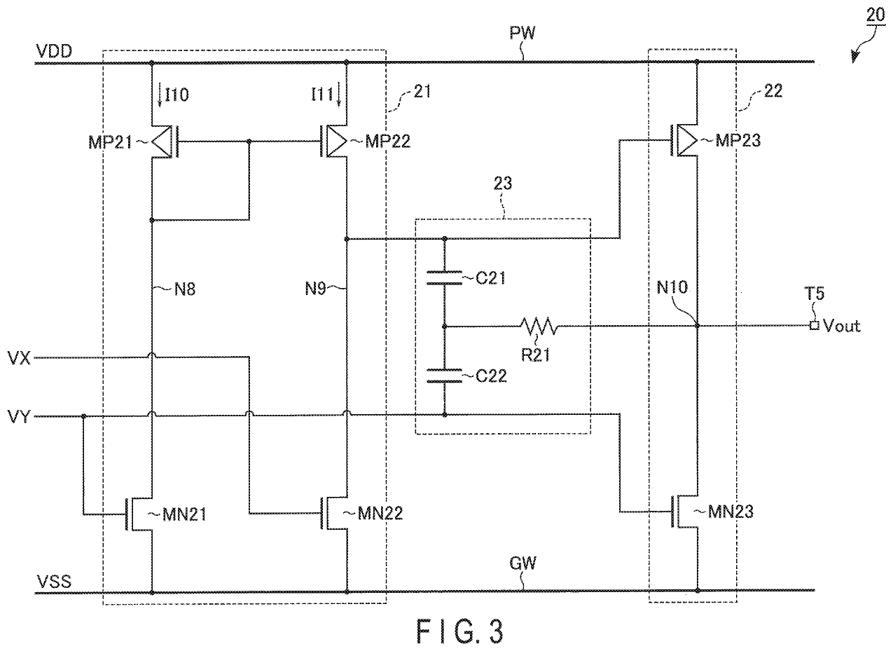

FIG. 3 shows an example of a circuit configuration of the output circuitry 20 included in the operational amplifier 1 according to the first embodiment. As shown in FIG. 3, the output circuitry 20 includes a drive circuit 21, an output circuit 22, and a phase compensation circuit 23.

The drive circuit 21 generates a drive voltage based on the voltage of the node VX and the voltage of the node VY, and outputs the drive signal to a node N9. The drive circuit 21 includes, for example, transistors MP21 and MP22, and transistors MN21 and MN22. Each of the transistors MP21 and MP22 is, for example, a p-type MOSFET. Each of the transistors MN21 and MN22 is, for example, an n-type MOSFET.

The source of the transistor MP21 is coupled to the power line PW. The gate and the drain of the transistor MP21 are coupled to a node N8. The source of the transistor MP22 is coupled to the power line PW. The gate of the transistor MP22 is coupled to the node N8. The drain of the transistor MP22 is coupled to the node N9. The source of the transistor MN21 is coupled to the power line GW. The gate of the transistor MN21 is coupled to the node VY. The drain of the transistor MN21 is coupled to the node N8. The source of the transistor MN22 is coupled to the power line GW. The gate of the transistor MN22 is coupled to the node VX. The drain of the transistor MN22 is coupled to the node N9.

The output circuit 22 generates a signal Vout based on the voltage of the node VY and the voltage of the node N9, and outputs the signal Vout from the terminal T5. The output circuit 22 includes, for example, transistors MP23 and MN23. The transistor MP23 is, for example, a p-type MOSFET. The transistor MN23 is, for example, an n-type MOSFET.

The source of the transistor MP23 is coupled to a power line PW. The gate of the transistor MP23 is coupled to the node N9. The drain of the transistor MP23 is coupled to a node N10. The source of the transistor MN23 is coupled to the power line GW. The gate of the transistor MN23 is coupled to the node VY. The drain of the transistor MN23 is coupled to the node N10.

The phase compensation circuit 23 compensates for phase characteristics of the operational amplifier 1. The phase compensation circuit 23 includes a resistor element R21 and capacitor elements C21 and C22.

One end of the resistor element R21 is coupled to the node N10. The other end of the resistor element R21 is coupled to one of the electrodes of the capacitor element C21, and to one of the electrodes of the capacitor element C22. The other electrode of the capacitor element C21 is coupled to the node N9. The other electrode of the capacitor element C22 is coupled to the node VY.

In the drive circuit 21 included in the output circuitry 20 described above, the transistor MP21 and the transistor MP22 are substantially equal in size. Also, the transistor MN21 and the transistor MN22 are substantially equal in size. The node N10 is coupled to the terminal T5.

That is, the voltage of the node N10 in the output circuitry 20 corresponds to the signal Vout.

[1-2] Operation of Operational Amplifier 1

The operational amplifier 1 according to the first embodiment is capable of rail-to-rail input and output operation. That is, a voltage equal to or greater than the power-supply voltage VSS, and equal to or less than the power-supply voltage VDD, is input to the operational amplifier 1. The operational amplifier 1 outputs a voltage equal to or greater than the power-supply voltage VSS, and equal to or less than the power-supply voltage VDD, based on the input voltage. In rail-to-rail input and output operation, the differential circuitry 10 switches its operation according to the signals input to the terminals T3 and T4.

The operational amplifier 1 according to the first embodiment operates as a voltage follower circuit when the terminals T5 and T4 are coupled. Specifically, the operational amplifier 1 operates in such a manner that the signal Vout output from the terminal T5 and the signal INP input to the terminal T3 are equal. That is, the operational amplifier 1 operates in such a manner that the voltages of the terminals T3, T4, and T5 are equal.

A description will be given below of the detailed operation of each of the differential circuitry 10 and the output circuitry 20 when the operational amplifier 1 is used as a voltage follower circuit. In the description that follows, let us assume that the power-supply voltage VDD is applied to the terminal T1, the terminal T2 is grounded, and the signal INP is input to the terminal T3. To simplify the description, the voltage of the signal Vout will be denoted “Vout”, the voltage of the signal INP will be denoted “Vin”, the voltage of the node VX will be denoted “VX”, and the voltage of the node VY will be denoted “VY”.

[1-2-1] Operation of Differential Circuitry 10

A description will be given of the operation of the differential circuitry 10 according to the first embodiment, with reference to FIG. 2. When the signal INP is input to the operational amplifier 1, the gates of the transistors MP11 and MN11 are respectively applied with the voltage Vin. At this time, the current I1 is supplied to the node N1 from the constant current source CS1, and the gate of the transistor MP13 is applied with the voltage V1.

The operation of the differential circuitry 10 according to the first embodiment changes based on the magnitude relationship of the voltages Vin and V1. For the operational amplifier 1, there will be, for example, three possible operating points: (1) case where Vin is less than V1, (2) case where Vin is greater than V1, and (3) case where Vin is substantially equal to V1.

<(1) Case where Vin is Less than V1>

In the case where Vin is less than V1, the transistors MP11 and MP12 are turned on, and the transistor MP13 is turned off. That is, the first differential circuit 11 is turned on, the current I2 flows from the transistor MP11 to the node N2, and the current I3 flows from the transistor MP12 to the node N3. With the transistor MP13 turned off, the current path between the nodes N1 and N4 is cut off. This gives I1=I2+I3. Since the current I2 and the current I3 are substantially equal in the present example,

I2=I3=(½)×I1.

When the transistor MP13 is turned off, the voltage of the node N4 decreases, and the transistor MN13 is turned off. With the transistor MN13 turned off, the transistor MN14, forming a current mirror circuit with the transistor MN13, is also turned off. With the transistor MN14 turned off, the amount of current at the node N5 decreases, and the transistors MN11 and MN12 are turned off. That is, the second differential circuit 12 is turned off, and the current path between the node N5 and each of the nodes N6 and N7 is cut off.

Consequently, a current I8, which flows through the transistor MN17, is equal to the sum of the current I3 and the current I6; and a current I9, which flows through the transistor MN18, is equal to the sum of the current I2 and the current I7. Based on these relationships, the current I8, which flows through the transistor MN17, can be expressed as follows: I8=I6+(½)×I1.

Since the gate of the transistor MN17 is coupled to the source of the transistor MN17 via the transistor MN15, the gate voltage of the transistor MN17 (namely, the voltage of the node VX) is determined by the current flowing through the transistor MN17 and the characteristics of the transistor MN17. Specifically, the voltage of the node VX can be expressed, using the basic formula for the strong-inversion operation of the MOS, as follows: VX=β√(2×(I6+(½)×I1))+VthMN17, where β is a value determined by the processing and the size of the transistor, and VthMN17 is the threshold voltage of the transistor MN17.

Unlike the node VX, the node VY is not coupled to the gates of the transistors included in the folded cascode circuit 14. Thus, the operating point of the node VY is determined by the output circuitry 20 coupled to the node VY outside the differential circuitry 10.

<(2) Case where Vin is Greater than V1>

In the case where Vin is greater than V1, the transistors MP11 and MP12 are turned off, and the transistor MP13 is turned on. That is, the first differential circuit 11 is turned off, and the current path between the node N1 and each of the nodes N2 and N3 is cut off.

The transistor MP13 is turned on, and the current flows from the transistor MP13 to the node N4. The amount of current that flows through the node N4 is substantially equal to the current I1. When the transistor MP13 is turned on, the voltage of the node N4 increases, and the transistor MN13 is turned on. With the transistor MN13 turned on, the transistor MN14, forming a current mirror circuit with the transistor MN13, is also turned on. With the transistor MN14 turned on, the voltage of the node N5 decreases, and the transistors MN11 and MN12 are turned on. That is, the second differential circuit 12 is turned on, the current I4 flows from the node N6 to the transistor MN11, and the current I5 flows from the node N7 to the transistor MN12. The amount of current that flows from the node N5 to the transistor MN14 is substantially equal to the sum of the currents I4 and I5. Since the transistor MN14 and the transistor MN13 are substantially equal in size, the amount of current that flows through the node N5 and the amount of current that flows through the node N4 are substantially equal. That is, the amount of current that flows through the node N5 is substantially equal to the current I1. Since the current I4 and the current I5 are substantially equal in the present example, I4=I5=(½)×I1.

Consequently, the current I8, which flows through the transistor MN17, takes the value obtained by subtracting the current I5 from the current I6; and the current I9, which flows through the transistor MN18, takes the value obtained by subtracting the current I4 from the current I7. Based on these relationships, the current I8, which flows through the transistor MN17, can be expressed as follows: I8=I6−(½)×I1. Thus, the voltage of the node VX can be expressed as follows: VX=β√(2×(I6−(½)×I1))+VthMN17.

<(3) Case where Vin is Substantially Equal to V1>

In the case where Vin is substantially equal to V1, the transistors MP11, MP12, and MP13 are turned on. That is, the first differential circuit 11 and the second differential circuit 12 are turned on, and the sum of the current flowing through the first differential circuit 11 and the current flowing through the second differential circuit 12 is substantially equal to the current I1. Consequently, the current I8, which flows through the transistor MN17, takes a value between the value in the above-described case (1) and the value in the above-described case (2). Thus, the voltage of the node VX takes a value between the value in the above-described case (1) and the value in the above-described case (2).

[1-2-2] Operation of Output Circuitry 20

Next, a description will be given of the operation of the output circuitry 20 based on the above-described operation of the differential circuitry 10, with reference to FIG. 3. The output circuitry 20 determines the operating point of the node VY based on the voltage of the node VX, and generates a signal Vout based on the voltages of the nodes VX and VY.

A description will be given of the method of determining the operating point of the node VY at the output circuitry 20. At the output circuitry 20, the transistor MN22 supplies a current based on the voltage of the node VX, coupled to its gate, from the node N9 to the power line GW. A current I11, which flows through the transistor MN22, is supplied from the transistor MP22. The transistors MP21 and MP22 are substantially equal in size, and form a current mirror circuit. Thus, the transistor MP21 supplies a current I10, which is substantially equal to the current I11, to the transistor MN21.

The gate voltage of the transistor MN21 is based on the current I10 supplied from the transistor MP21. The transistors MN21 and MN22 are provided in a substantially equal size, and the currents flowing therethrough are substantially equal. Thus, the voltage of the node VY, to which the gate of the transistor MN21 is coupled, and the voltage of the node VX, to which the gate of the transistor MN22 is coupled, are substantially equal.

A description will be given of the method of generating the signal Vout at the output circuitry 20. At the output circuitry 20, the drive circuit 21 controls the voltage of the node N9 based on differential signals output to the nodes VX and VY from the differential circuitry 10, thereby controlling the transistor MP23 included in the output circuit 22. Specifically, the differential signals of the nodes VX and VY are respectively input to the gates of the transistors MN22 and MN21. The transistors MN21 and MN22 are coupled to a current mirror circuit formed of the transistors MP21 and MP22. This allows the differential signals of the nodes VX and VY to be synthesized at the node N9. The signal of the node N9 can be thus used to control the transistor MP23.

The output circuit 22 outputs the signal Vout to the terminal T5, based on the voltages of the nodes N9 and VY. Specifically, the transistor MP23 outputs a voltage to the terminal T5, based on the voltage of the node N9. The transistor MN23 outputs a voltage to the terminal T5, based on the voltage of the node VY. A signal Vout, obtained by synthesizing the outputs of both of the transistors MP23 and MN23, is output to the terminal T5.

[1-3] Advantageous Effects of First Embodiment

According to the above-described operational amplifier 1 of the first embodiment, it is possible to suppress an offset voltage, thus improving the operation reliability. Advantageous effects of the operational amplifier 1 according to the first embodiment will be described in detail below.

When the operational amplifier is used as, for example, a voltage follower circuit, it is desirable that the non-inverting input and the output signal be at the same voltage. However, in an operational amplifier, a difference may be caused in the output voltage by variations, etc. between the element on the non-inverting input side and the element on the inverting input side. Such a difference in voltage between the non-inverting input and the output signal is called, for example, “an offset voltage”. In an operational amplifier, it is preferable that the offset voltage be close to 0 V.

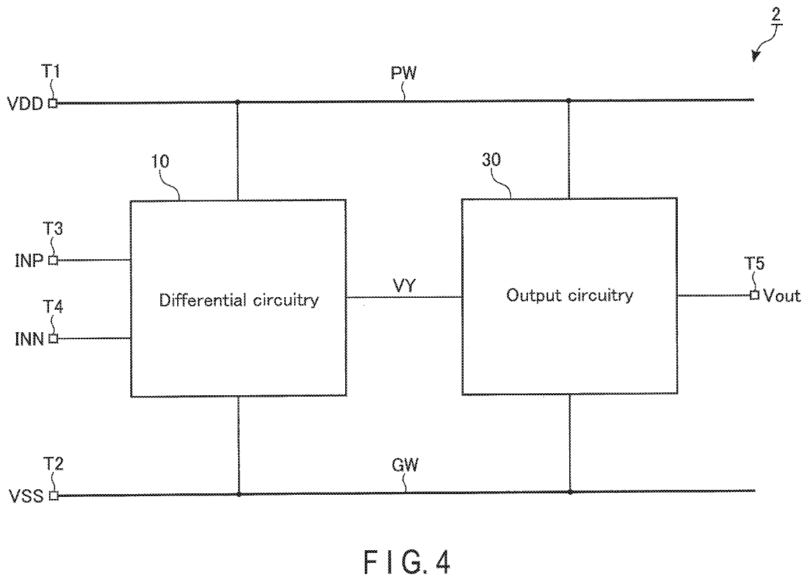

FIG. 4 illustrates a configuration example of an operational amplifier 2 according to a comparative example of the first embodiment. The operational amplifier 2 according to the comparative example is configured in such a manner that the output circuitry 20 of the operational amplifier 1 according to the first embodiment, described with reference to FIG. 1, is replaced by output circuitry 30. As shown in FIG. 4, the output circuitry 30 is coupled only to a node VY of the differential circuitry 10, in the operational amplifier 2 according to the comparative example. That is, a node VX is not coupled to the output circuitry 30 in the operational amplifier 2 according to the comparative example.

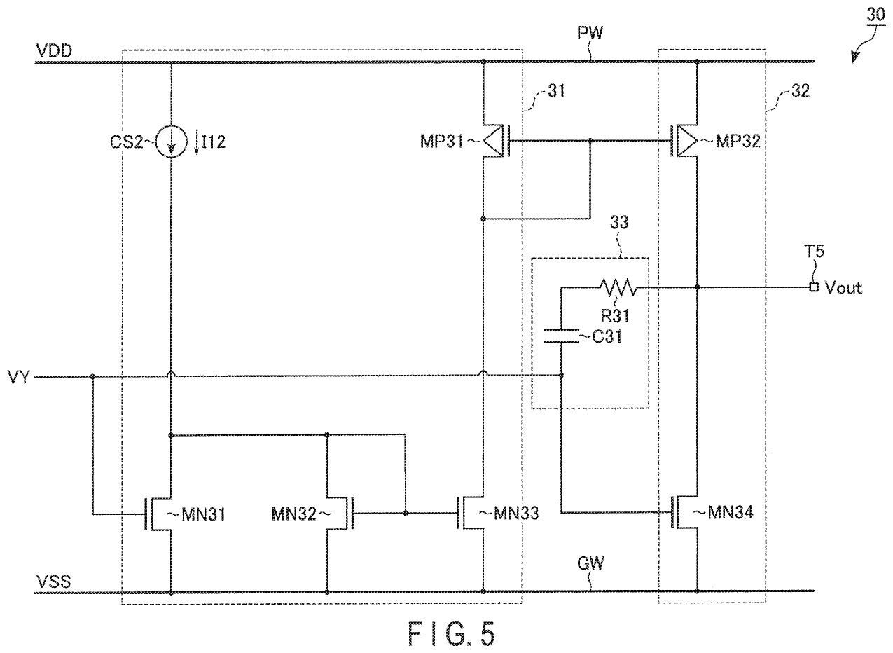

FIG. 5 is a circuit diagram of the output circuitry 30, included in the operational amplifier 2 according to the comparative example of the first embodiment. As shown in FIG. 5, the output circuitry 30 includes a drive circuit 31, an output circuit 32, and a phase compensation circuit 33. The drive circuit 31 generates a signal for driving a transistor MP32, included in the output circuit 32, based on the voltage of the node VY. The drive circuit 31 determines the operating point of the node VY. In the operational amplifier 2 according to the comparative example, the operating point of the node VY is the voltage based on the current I12 supplied from the constant current source CS2 and the characteristics of the transistor MN31. The output circuit 32 outputs the signal Vout, based on the signal generated by the drive circuit 31 and the signal of the node VY. The phase compensation circuit 33 compensates for phase characteristics of the operational amplifier 2.

In the operational amplifier 2 according to the comparative example, the voltage of the node VY is determined by the output circuitry 30. On the other hand, the voltage of the node VX changes according to the voltages of the terminals T3 and T4. The node VX, though not illustrated, is included in the differential circuitry 10 of the operational amplifier 2. That is, in the operational amplifier 2 according to the comparative example, a difference may be generated between the voltage of the node VX and the voltage of the node VY.

In contrast, the operational amplifier 1 according to the first embodiment includes the output circuitry 20 coupled to the nodes VX and VY. In the operational amplifier 1 according to the first embodiment, the output circuitry 20 determines the voltage of the node VY to be equal to the voltage of the node VX. That is, the operational amplifier 1 according to the first embodiment is configured in such a manner that, when the voltage of the node VX changes, the voltage of the node VY also changes to be equal thereto, thus keeping the voltages of the nodes VX and VY substantially equal.

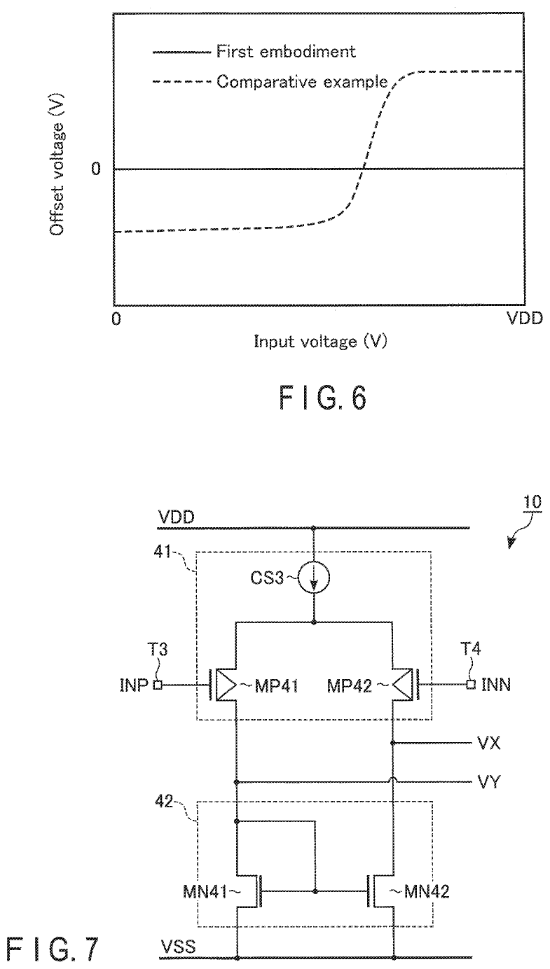

FIG. 6 illustrates an example of a relationship between an input voltage and an offset voltage in each of the operational amplifier 1 according to the first embodiment and the operational amplifier 2 according to the comparative example of the first embodiment. Specifically, FIG. 6 illustrates an example in which each of the operational amplifiers 1 and 2 is used as a voltage follower circuit, and the input voltage falls within the range from 0 V to VDD. In FIG. 6, the lateral axis represents the input voltage (e.g., the voltage input to the terminal T3), and the vertical axis represents the offset voltage. As illustrated in FIG. 6, the offset voltage of the operational amplifier 2 according to the comparative example fluctuates from a negative value to a positive value, according to the voltage applied to the terminal T3. On the other hand, changes in the offset voltage of the operational amplifier 1 according to the first embodiment are suppressed, regardless of the input voltage; namely, the voltage applied to the terminal T3.

By thus setting the voltages of the nodes VY and VX to be substantially equal, using the output circuitry 20, the operational amplifier 1 according to the first embodiment is capable of suppressing the offset voltage. In addition, since the operational amplifier 1 according to the first embodiment is capable of suppressing a change in the offset voltage caused by a change in the voltage applied to the terminal T3, it is possible to achieve a high common-mode rejection ratio (CMRR).

The above-described operational amplifier 1 according to the first embodiment is capable of suppressing the offset voltage even during a low-voltage operation. This advantageous effect will be described below, by taking an example in which the operational amplifier 1 is operated as a voltage follower at a low power-supply voltage.

A transistor switches from operating in the saturation region to operating in the non-saturation region when, for example, the drain-to-source voltage decreases. A transistor has different characteristics when operating in the saturation region when operating in the non-saturation region. It is thus desirable that each of the paired transistors operate in the same region, in a circuit that performs, for example, differential amplification. In order to allow a transistor to operate in the saturation region during a low-voltage operation, it is effective to design the threshold voltage of the transistor to be low. In the present example, let us assume that the differential circuitry 10 is formed of transistors with low threshold voltages.

When the differential circuitry 10 is designed in such a manner that the transistors MN15 to MN18 operate in the saturation region while Vin is between 0 V and V1, the transistor MN15 is apt to operate in the non-saturation region while Vin is between V1 and VDD. When, for example, the operating points of the transistors MN15 and MN16 differ, the transistor MN15 is apt to operate in the non-saturation region, and the transistor MN16 is apt to operate in the saturation region. Consequently, the operational amplifier may have a high offset voltage during a low-voltage operation, causing deterioration in the CMRR.

In the operational amplifier 2 according to the comparative example, the voltage of the node VY is determined by the output circuitry 30. In this case, the drain-to-source voltage of the transistor MN16 may be greater than the drain-to-source voltage of the transistor MN15. Thus, in the operational amplifier 2 according to the comparative example, the transistor MN15 may operate in the non-saturation region, and the transistor MN16 may operate in the saturation region.

In contrast, in the operational amplifier 1 according to the first embodiment, the voltage of the node VY is set by the output circuitry 20 to be substantially equal to the voltage of the node VX. Thus, in the operational amplifier 1 according to the first embodiment, it can be expected that, when the transistor MN15 switches to operating in the non-saturation region, the transistor MN16 also switches to operating in the non-saturation region.

This allows the paired transistors to operate in the non-saturation region in differential amplification, even when the power-supply voltage is low, in the operational amplifier 1 according to the first embodiment. Consequently, the operational amplifier 1 according to the first embodiment is capable of suppressing the offset voltage even during a low-voltage operation.

### [2] Second Embodiment

An operational amplifier 1 according to the second embodiment differs from the operational amplifier 1 according to the first embodiment in terms of the circuit configuration of the differential circuitry 10. Differences from the first embodiment will be described below, with reference to the operational amplifier 1 according to the second embodiment.

[2-1] Configuration of Operational Amplifier 1

FIG. 7 is a circuit diagram of the differential circuitry 10 included in the operational amplifier 1 according to the second embodiment. As shown in FIG. 7, the differential circuitry 10 includes a differential circuit 41 and a current mirror circuit 42.

The differential circuit 41 includes, for example, transistors MP41 and MP42, and a constant current source CS3. Each of the transistors MP41 and MP42 is, for example, a p-type MOSFET.

The constant current source CS3 is coupled between a power line PW and the source of each of the transistors MP41 and MP42. The constant current source CS3 is applied with, for example, the power-supply voltage VDD, and supplies the constant current to the source of each of the transistors MP41 and MP42. The gate of the transistor MP41 is coupled to the terminal T3. The drain of the transistor MP41 is coupled to the node VY. The gate of the transistor MP42 is coupled to the terminal T4. The drain of the transistor MP42 is coupled to the node VX.

The current mirror circuit 42 includes transistors MN41 and MN42. Each of the transistors MN41 and MN42 is, for example, an n-type MOSFET.

The source of the transistor MN41 is coupled to the power line GW. The gate and the drain of the transistor MN41 are coupled to the node VY. The source of the transistor MN42 is coupled to the power line GW. The gate of the transistor MN42 is coupled to the node VY. The drain of the transistor MN42 is coupled to the node VX.

As described above, the operational amplifier 1 according to the second embodiment includes the differential circuitry 10, which includes the differential circuit 41 formed of, for example, a p-type MOSFET, and not including a differential circuit formed of an n-type MOSFET. The other configuration of the operational amplifier 1 according to the second embodiment is similar to that of the operational amplifier 1 according to the first embodiment, and detailed descriptions thereof will be omitted.

[2-2] Advantageous Effects of Second Embodiment

In the above-described operational amplifier 1 according to the second embodiment, the differential circuitry 10 differentially amplifies the signal input to the terminal T3 and the signal input to the terminal T4, and outputs the differentially amplified signals to the nodes VX and VY. The output circuitry 20 operates in a manner similar to the first embodiment. That is, the output circuitry 20 in the second embodiment operates in such a manner that the voltage of the node VX and the voltage of the node VY are equal. In the operational amplifier 1 according to the second embodiment, it is possible to suppress the offset voltage and to achieve a high CMRR, as in the first embodiment, even though the operable input range is equal to or greater than the power-supply voltage VSS, and less than the power-supply voltage VDD, making it difficult to perform a rail-to-rail input operation.

### [3] Other Modifications

Various modifications may be made to the circuit configuration of the operational amplifier 1 according to the above-described embodiments. For example, in each of the operational amplifiers 1 according to the first and second embodiments, the transistors may be switched between the n-type and the p-type. In other words, in each of the operational amplifiers 1 according to the first and second embodiments, the transistors described as being p-type MOSFETs may be replaced by n-type MOSFETs, and those described as being n-type MOSFETs may be replaced by p-type MOSFETs.

When such switching of the transistors between the n-type and the p-type is adopted in the operational amplifier 1, the coupling direction of the constant current source, the power-supply voltage, etc., may also be suitably changed. Specifically, when the transistors are switched between the n-type and the p-type in the operational amplifier 1 according to the first embodiment, the configuration is changed in such a manner that the power line PW is grounded, the power-supply voltage VDD is applied to the power line GW, and the constant current source CS1 allows a current to flow from the node N1 to the power line PW. When the transistors are switched between the n-type and the p-type in the operational amplifier 1 according to the second embodiment, the configuration is changed in such a manner that the power line PW is grounded, the power-supply voltage VDD is applied to the power line GW, and the constant current source CS3 allows a current to flow from the other end of each of the transistors MP41 and MP42 to the power line PW.

In the operational amplifier 1 according to the first embodiment, when the transistors in the output circuitry 20 are switched between the n-type and the p-type, the current mirror coupling in the folded cascode circuit 14 of the differential circuitry 10 is changed from the n-type to the p-type. Specifically, the gates of the transistors MN17 and MN18 are applied with the voltage V5, instead of being coupled to the drain of the transistor MN15. In addition, the gates of the transistors MP14 and MP15 are coupled to the node VX, instead of being applied with the voltage V4. In the operational amplifier 1 according to the first embodiment, the circuit configuration of the differential circuitry 10 may be modified in the above-described manner.

In the present specification, “capable of rail-to-rail input and output operation” means that the operational amplifier 1, which operates on two power-supply rails (e.g., VDD and VSS), is capable of inputting and outputting voltages ranging from a voltage substantially equal to VDD to a voltage substantially equal to VSS. Such an operation of the operational amplifier 1 may be rephrased as “permitting a full-swing input and output operation”.

In the above-described embodiments, a case has been described, as an example, where the operational amplifier 1 is used as a voltage follower circuit; however, the application of the operational amplifier 1 is not limited thereto. The operational amplifier 1 may be used, for example, as a non-inverting amplification circuit having a voltage gain, or alternatively as an inverting amplifier circuit, or even as a filter circuit having frequency characteristics. The operational amplifier 1 according to the above-described embodiments is capable of suppressing the offset voltage in various applications.

In the present embodiment, the “size” of a transistor means, for example, the gate length and the gate width of the transistor. When the same voltage is applied between the gate and the source of each of a plurality of transistors equal in size, the current-driving capabilities of the transistors are equal. When the same amount of current flows between the drain and the source of each of a plurality of transistors equal in size, the gate-to-source voltages of the transistors are equal. Even when the manufactured transistors have slightly different sizes due to variations in processing, etc., such sizes can be expressed as being substantially equal, and their current drivabilities can be expressed as being substantially equal. When substantially the same amounts of current flow through a plurality of transistors substantially equal in size, the gate-to-source voltages of the transistors can be expressed as being substantially equal.

The operational amplifier according to the embodiments may be incorporated into various devices. For example, the operational amplifier may be incorporated into personal computers, mobile communication devices such as mobile phones, Internet of things (IoT) sensors, household electrical goods, etc.

In the present specification, the term “couple” refers to electrical coupling, and does not exclude intervention of, for example, another element. In addition, “electrical coupling” may be performed via an insulator, if the same operation is ensured thereby.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An operational amplifier comprising:
a first input terminal;
a second input terminal;
an output terminal;
differential circuitry including: a first node, a second node, a first transistor, and a second transistor, the first transistor being coupled to the first input terminal at a gate and coupled to the first node at one end, the second transistor being coupled to the second input terminal at a gate, coupled to the second node at one end, and coupled to another end of the first transistor at another end; and
output circuitry including a third node, a fourth node, a fifth node, a third transistor, a fourth transistor, a fifth transistor, a sixth transistor, a seventh transistor, and an eighth transistor, the fifth node being coupled to the output terminal, the third transistor being coupled to the first node at a gate and coupled to the third node at one end, the fourth transistor being coupled to the second node at a gate and coupled to the fourth node at one end, the fifth transistor being coupled to the fourth node at a gate and coupled to the third node at one end, the sixth transistor being coupled to the fourth node at each of a gate and one end, the seventh transistor being coupled to the second node at a gate and coupled to the fifth node at one end, and the eighth transistor being coupled to the third node at a gate and coupled to the fifth node at one end.

2. The operational amplifier according to claim 1, wherein
the third transistor and the fourth transistor are substantially equal in size, and
the fifth transistor and the sixth transistor are substantially equal in size.

3. The operational amplifier according to claim 1, further comprising:
a first power line to which another end of the third transistor, another end of the fourth transistor, and another end of the seventh transistor are coupled;
a second power line to which another end of the fifth transistor, another end of the sixth transistor, and another end of the eighth transistor are coupled;
a first power-supply terminal coupled to the first power line; and
a second power-supply terminal coupled to the second power line.

4. The operational amplifier according to claim 3, wherein
the differential circuitry further includes:
a ninth transistor and a tenth transistor, the ninth transistor being coupled to the first input terminal at a gate and coupled to the first node at one end, the tenth transistor being coupled to the second input terminal at a gate, coupled to the second node at one end, and coupled to another end of the ninth transistor at another end, the ninth transistor and the tenth transistor being of a first conductivity type, and the first transistor and the second transistor being of a second conductivity type different from the first conductivity type.

5. The operational amplifier according to claim 4, wherein
the differential circuitry further includes a current control circuit, and
the current control circuit supplies a current to at least one of a pair of the first transistor and the second transistor, and a pair of the ninth transistor and the tenth transistor, based on a voltage of the first input terminal and a voltage of the second input terminal.

6. The operational amplifier according to claim 4, wherein
the differential circuitry further includes: an eleventh transistor, a twelfth transistor, a thirteenth transistor, a fourteenth transistor, a fifteenth transistor, a sixteenth transistor, a seventeenth transistor, and an eighteenth transistor, the eleventh transistor being coupled between one end of the first transistor and the first node, the twelfth transistor being coupled between one end of the second transistor and the second node, the thirteenth transistor being coupled between one end of the first transistor and the first power line, the fourteenth transistor being coupled, at a gate, to a gate of the thirteenth transistor and the first node and coupled between one end of the second transistor and the first power line, the fifteenth transistor being coupled between one end of the ninth transistor and the first node, the sixteenth transistor being coupled between one end of the tenth transistor and the second node, the seventeenth transistor being coupled between one end of the ninth transistor and the second power line, and the eighteenth transistor being coupled between one end of the tenth transistor and the second power line.

7. The operational amplifier according to claim 6, wherein
the third transistor, the fourth transistor, the seventh transistor, the eleventh transistor, the twelfth transistor, the thirteenth transistor, and the fourteenth transistor are of the first conductivity type, and the fifth transistor, the sixth transistor, the eighth transistor, the fifteenth transistor, the sixteenth transistor, the seventeenth transistor, and the eighteenth transistor are of the second conductivity type.

8. The operational amplifier according to claim 1, wherein
a voltage of the first node and a voltage of the second node are substantially equal, if the first input terminal and the output terminal are coupled, and a voltage of the first input terminal, a voltage of the second input terminal, and a voltage of the output terminal are substantially equal.

9. The operational amplifier according to claim 1, wherein
the third transistor, the fourth transistor, and the seventh transistor are of a first conductivity type, the fifth transistor, the sixth transistor, and the eighth transistor are of a second conductivity type different from the first conductivity type.

10. The operational amplifier according to claim 1, wherein
the differential circuitry further includes a nineteenth transistor and a twentieth transistor, the nineteenth transistor being coupled, at each of a gate and one end, to the second node, and the twentieth transistor being coupled to the first node at one end and coupled to the second node at a gate.

11. The operational amplifier according to claim 10, wherein
the third transistor, the fourth transistor, the seventh transistor, the nineteenth transistor, and the twentieth transistor are of a first conductivity type, and the first transistor, the second transistor, the fifth transistor, the sixth transistor, and the eighth transistor are of a second conductivity type different from the first conductivity type.
